(19) United States
(12) Patent Application Publication
(10) Pub. No.: US 2021/0384892 A1
(43) Pub. Date: Dec. 9, 2021

(54) PARALLEL IMPLEMENTATIONS OF FRAME FILTERS WITH RECURSIVE TRANSFER FUNCTIONS

(71) Applicant: The MathWorks, Inc., Natick, MA (US)

(72) Inventor: Alireza Pakyari, Waltham, MA (US)

(21) Appl. No.: 16/990,291

(22) Filed: Aug. 11, 2020

Related U.S. Application Data
(60) Provisional application No. 63/036,670, filed on Jun. 9, 2020.

(51) Int. Cl. H03H 17/02; H03H 17/04; H03H 15/00; H03H 21/00; H04B 1/00

(52) U.S. Cl. CPC H03H 17/0277; H03H 17/04; H04B 1/0017; H03H 21/0012; H03H 15/023

(57) ABSTRACT

The exemplary embodiments provide a parallel implementation of filters with recursive transfer functions. This can enable a filter to act as a frame filter that may process a frame of multiple samples of data in parallel rather than being limited to processing a single sample of data at a time. Each frame contains plural input samples of data values. The input samples are from a common source and have a time dependency. The exemplary embodiments are suitable for implementing various types of filters in parallel, such as cascaded integrator comb filters, biquad filters and other types of infinite impulse response (IIR) filters. The exemplary embodiments may use polyphase decomposition to decompose a filter with a recursive transfer function into multiple polyphase component filters. The polyphase component filters may be applied to respective samples of data in a parallel pipelined configuration to produce filtered output for the samples of data in parallel.

### SUMMARY

In accordance with an exemplary embodiment, a method is performed in which two or more input samples of data values are received. A filter operation is performed on a first and a second input sample of data values in parallel to obtain filtered first and second input samples of data values. The filter operation comprises a recursive filter operation such that the filtering of the second input sample of data values that is subsequent in time relative to the first input sample of data values is dependent on the filtering of the first input sample of data values. The applying the filter operation comprises performing, with processing logic, polyphase decomposition of the recursive filter operation to generate a first filter operation for the first input sample of data values and a second filter operation for the second input sample of data values that filters the second input sample of data values independent of the first filter operation. The applying the filter operation also comprises performing the first and second filter operations on the first and second input samples of data values in parallel to produce the filtered first and second data input sample values.

The applying a filter operation may comprise applying one of a cascaded integrator comb (CIC) filter operation, a biquad filter operation or an infinite impulse response (IIR) filter operation. The two or more input samples of data values may be received in parallel as part of a frame, they may be from a common source, there may be a dependency between the data values and the filter operation may be performed on the two or more input samples in the frame in parallel. There may be more than two input samples of data values in the frame. There may be N input samples in the frame, where N is a positive integer, and wherein the performing, with the processing logic, the polyphase decomposition of the recursive filter operation decomposes the recursive filter operation into N filter operations for filtering N input samples of data values. A magnitude of N may be dictated by storage considerations and/or power considerations. The method may be performed by executing a model on one or more processors and wherein the model may include a modeled filter that performs applying of the filter operation on the first and second input samples of data values. The method may be performed by a physical device. The method may further include generating programming language instructions from the model, wherein when executed the programming language instructions perform the method. The programming language instructions may be generated in one of the following programming languages: VHDL language, Verilog language, C language C++ language, Python language, or Java language The processing logic may be one of a central processing unit (CPU), a graphics processing unit (GPU), a field programmable gate array (FPGA), an application specific integrated circuit (ASIC), an Application Specific Instruction set Processor (ASIP) or a digital signal processor (DSP).

A non-transitory computer-readable storage media may store instructions executable by processing logic to cause the processing logic to perform the method. Processing logic may be configured to perform the method. The processing logic may include multiple cores, processors and/or logic elements for performing the first filter operation and the second filter operation in parallel.

In accordance with an exemplary embodiment, a method includes analyzing a model that comprises model portions representing functionalities of a recursive filter operation on two or more input samples of data values, wherein the filtering of the second input sample of data values that is subsequent in time relative to the first input sample of data values is dependent on the filtering of the first input sample of data values. Program code for the model is generated, wherein generating the program code comprises generating first program code for a filter operation to apply on a first input sample of data values, and generating second program code for a filter operation to apply on a second input sample of data values, The first filter operation and the second filter operation are polyphase decomposed filter operations of the recursive filter operation, and the first program code and second program code are executable in parallel to obtain filtered first and second input samples of data values.

The generating code may include analyzing the model. The analyzing may also include polyphase decomposition of a transfer function for the recursive filter operation. The generated program code may include code generated in one of the following programming languages: VHDL language, Verilog language, C language C++ language, Python language, or Java language.

A non-transitory computer-readable storage media may store instructions executable by processing logic to cause the processing logic to perform the method. Processing logic may be configured to perform the method. The processing logic may include multiple cores, processors and/or logic elements for performing the first filter operation and the second filter operation in parallel.

### BRIEF DESCRIPTION OF THE DRAWINGS

FIG. 1 depicts a wireless receiver environment suitable for using a frame filter per an exemplary embodiment.

FIG. 2 depicts filtering of example frames of input samples by a filter.

FIG. 3A depicts a portion of an example digital processing logic that performs filtering.

FIG. 3B depicts a diagram of possible types of processing logic that may be used in exemplary embodiments.

FIG. 4 depicts a flowchart of example steps that may be performed to apply polyphase decomposition to implement a frame filter in exemplary embodiments.

FIG. 5 depicts a block diagram of an example serial CIC filter.

FIG. 6A depicts an illustrative block diagram model for an example filter with cascaded transfer functions.

FIG. 6B depicts an illustrative block diagram model for a filter with cascaded transfer functions having a down sampling component.

FIG. 6C depicts an illustrative block diagram model for another example filter with cascaded transfer functions having a up sampling component.

FIG. 7A depicts a block diagram of an example frame-based CIC filter.

FIG. 7B depicts an illustrative block diagram model for the Q₀(z) blocks of FIG. 7A.

FIG. 7C depicts an illustrative block diagram model for the Q₁(z) blocks of FIG. 7A.

FIG. 8 depicts a block diagram of an example frame-based biquad filter.

FIG. 9A depicts a flowchart of illustrative steps that may be performed where polyphase decomposition is performed before simulation of a model.

FIG. 9B depicts a flowchart of illustrative steps that may be performed where polyphase decomposition is performed during simulation of a model.

FIG. 10 depicts a flowchart of illustrative steps for generating code from a model of a filter and using on target hardware.

FIG. 11 depicts a block diagram of a computing device suitable for practicing an exemplary embodiment.

FIG. 12 depicts a block diagram of a distributed computing environment suitable for practicing an exemplary embodiment.

FIG. 13 depicts an illustrative simulation environment with an executable simulation model and generated code.

FIG. 14 depicts an example of an illustrative electronic device having processing logic for implementing a filter for an exemplary embodiment.

### DETAILED DESCRIPTION

Filtering operations may be used to enhance or suppress short-term trends in a time sequence of data (e.g., a stream of data representing a sampled, time-evolving signal). For example, a low-pass filter operation can be implemented in computing code as a filtering function and applied to a data sequence representative of a slowly varying signal to suppress high-frequency noise that may be corrupting the signal. As another example, a band-pass filter operation can be implemented to enhance irregularities within a certain frequency band for a received signal (e.g., to detect arrhythmia in a cardiac pulse waveform). Another example of filtering may be implementing a high-pass filter (e.g., one that passes signal components at frequencies above a desired cut-off frequency and blocks or suppresses signal components at frequencies below the cut-off frequency). A high-pass filter can be used to reduce or remove systematic measurement errors from a signal of interest. For example, slowly varying temperature changes can add long-term drift to sensed signals produced by a strain-gauge sensor, and such drift in the measured signal can be removed by a high-pass filter.

Filtering of data is widely used in signal processing and data analytic fields. Examples for which filtering according to the exemplary embodiments can be applied include but are not limited to communication signals, such as radio communication signals, microwave communication signals or line communication signals, and systems (wired or wireless), imaging signals and systems (e.g., radio telescope signals and systems, coherence tomography signals and systems, radar and/or lidar imaging signals and systems), radio frequency signals (e.g., cellular phone network signals, television signals, GPS signals or software defined radio (SDR) signals), wireless communication signals (e.g., signals in wireless networks, such as WiFi), video signals (e.g., from image capture devices, video cameras, stream servers that stream video content), audio signals (e.g. in audio components) medical signals and systems (e.g., EEG, ECG, heart-rate monitors, glucose monitors, etc.), sensor networks deployed for monitoring complex physical or biophysical systems (e.g., machines, distributed power systems, meteorological systems, oceanic systems, seismology systems, human body, etc.), and advanced driver-assistance systems.

The filtering may occur on a transmitting side of a system and/or a receiving side of a system. Examples of devices where the filtering may occur include but are not limited to radio receivers, including heterodyne, homodyne and superheterodyne receivers, television receivers, radar receivers, microwave receivers, satellite receivers, radio transmitters, audio receivers, television transmitters, radar transmitters, microwave transmitters, satellite transmitters and digital transceivers. The filtering may also take place immediately before or immediately after such devices in some instances.

The signals from which samples are taken and to which filtering applies may be real world signals from physical devices. Alternatively, the values to which filtering is applied may be synthesized or generated from simulations of physical devices.

The filtering may be applied to a time series of data. A time series is a sequence of data values in successive order. The data values may be sequenced by their associated times. As an example, if a signal is sampled at periodic sampling times, the samples of data values over time form a time series. A time series might be finite or infinite. For example, a time series may not have an upper bound on the number of elements in the time series and thus may be infinite. A frame of data may be a consecutive subset of time series. A frame of data also may be a subset of data values in the time series, such as consecutive data values in the time series. Each data in the time series might be multi-valued, for example, Real and Imaginary, or RGB.

The procedure for determining an output of the filter can be expressed by a transfer function H(z) for the filter expressed in z domain. The transfer function expresses how to produce the output Y(z) for the filter given the input X(z). In some embodiments, the data values are time-series data values, and the filter output of one data value can be dependent on one or more previous filter outputs for previous data values. A transfer function for such a filter is said to be recursive. Because the dependency, such filters with recursive transfer functions conventionally have operated serially in processing one sample of data, e.g., one data value, at a time. When the series of data to be filtered is large, the calculation of the transfer function in a serial manner can be very time consuming and can limit the throughput of the filter. Many systems employ filters with recursive transfer functions. Examples include the receivers, transmitters and transceivers identified above where filtering is used. The slowness of implementing the filters in a serial manner on the time series data samples may act as a bottleneck to the transmission speed in the systems. The slowness may cause samples of data values to be dropped as the filters may not keep pace with the rate of input samples of data values received.

Another benefit of parallel processing is to reduce power consumption. By parallel processing, the frequency of processing is reduced but resources usage is increased. Increasing resources increases power consumption proportional to parallel factor V (or frame size), but reduction of frequency reduces power by V², which is reduction in power consumption in total.

The exemplary embodiments provide a parallel implementation of filters with recursive transfer functions. This can enable a filter to act as a frame filter that may process a frame of multiple samples of data in parallel rather than being limited to processing a single sample of data at a time. Each frame contains plural input samples of data values. The input samples are from a common source and have a time dependency. For example, suppose that the input samples of data values are samples of a signal (i.e., a common source). If each frame contains two input samples of data values, the frame, for example, may contain a first input data sample of data values taken at a first sampling time and a second input sample of data values from a second sampling time that is the next consecutive sampling time. Thus, there is a dependency between the first input samples of data values and the second input sample of data values in that the input samples are taken from the same signal at consecutive sampling times. The input samples are filtered by a filter in parallel as will be described in more detail below. The result is much faster filtering.

The exemplary embodiments are suitable for implementing various types of filters in parallel, such as cascaded integrator comb filters, biquad filters, and other types of infinite impulse response (IIR) filters. The filters may be realized in software (e.g., a simulated or modeled filter in a software environment), hardware (e.g., processing logics or devices that implement the functionalities of a filter) or a hybrid (e.g., a configurable hardware device like an FPGA) thereof. The filters may act on real world signals or may act on simulated signals in simulation environments, as described above. In some exemplary embodiments. The filter may be simulated and operate on real signal data imported into a simulation environment or simulated signal data. Moreover, the filters may be part of models that are simulated by a simulation environment and from which programming language code may be generated, e.g., automatically generated by a coder, for implementing the filter on target processing logic. For example, the generated code may be generated in, the C programming language, the C++ programming language, a Hardware Description Language (HDL), (e.g., the Very High Speed Integrated Circuit Hardware Description Language (VHDL) or the Verilog language), the Python programming language or the Java programming language. The resulting code may be deployed to a target device as identified below to implement the filter.

The exemplary embodiments may use polyphase decomposition to decompose a filter with a recursive transfer function into multiple polyphase component filters. The polyphase component filters may be applied to respective samples of data in a parallel pipelined configuration to produce filtered output for the samples of data in parallel. As a result, frames of greater than one sample of data may be processed in parallel by the filter. This allows the throughput of the filter to be greatly increased compared to conventional serial filters, for example, so that input samples of data values are not dropped by the filter.

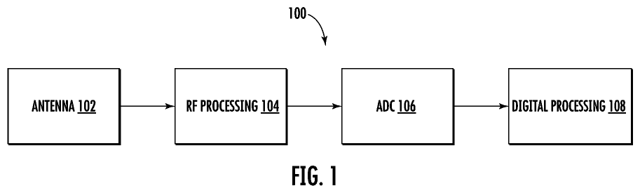

The lack of throughput of conventional filters with recursive transfer functions may be especially problematic in situations where input samples are received at high rates such that a conventional serial filter cannot process the input samples of data values in time because the conventional serial filter performs too slowly. FIG. 1 depicts an example environment 100 where a filter with a recursive transfer function may be deployed. In this example, the environment 100 is a wireless receiver environment, such as one in a cellular phone. A radio frequency (RF) signal may be received by an antenna 102. RF processing 104, such as some filtering and amplification, may then be performed on the received input. The processed RF signal is then sampled and digitized by an analog to digital converter (ADC) 106 to yield digital sample values. The ADC 106 may sample the RF signal directly. The high sampling frequency is driven by the high bandwidth of the signals being sampled and the Nyquist criterion. Higher frequency signals have higher bandwidth (i.e., the amount of data transferred per second) than lower frequency signals. The Nyquist criterion states that a repetitive waveform can be correctly reconstructed samples from provided that the sampling frequency is greater than double the highest frequency to be sampled.

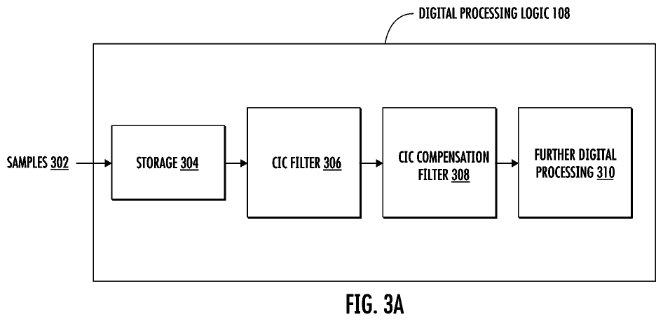

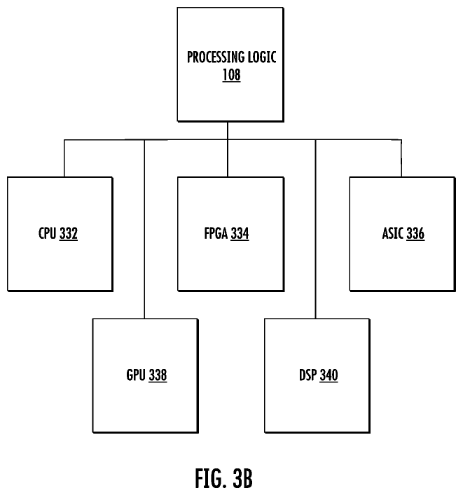

The samples then are passed to digital processing logic 108, which includes filtering for the incoming stream of samples output from the ADC 106 as shown in FIG. 3A. The filtering may include one or more filters with recursive transfer functions. An example of a filter with a recursive filter is a CIC filter 306. In the exemplary embodiments, the CIC filter 306 is frame-based (i.e., receives as input a frame of more than one input sample of data values and processes the more than one input sample of data values of the frame in parallel per cycle). In other words, the filter may process a frame of multiple samples of data values per cycle of the filter. The cycle of the filter refers to the duration of time that it takes for the filter to completely process one frame of samples of data values. The CIC filter performs low pass filtering and down samples the input from input samples 302. The samples 302 may be received by the digital processing logic 108 and stored in a storage 304. The storage 304 may be, for instance, a set of registers, in which samples 302 in the incoming stream may be stored one at a time as received. The storage may be of the size to hold a single frame of samples 302.

The frame size may be dictated by processing speed. For example, if the digital processing logic 108 can be run at a maximum of 500 MHz but the ADC 106 samples at a rate of 2 GHz, the frame size may be dictated to be 2 GHz/500 MHz or 4 samples per frame.

The frame size may also be dictated by power consumption. Suppose that the ADC 106 sampling rate is not too high for the digital processing logic 108 to handle. However, a decrease in power consumption is desired. With parallel processing, the number of resources is increased by a factor of N (where N is the number of samples in a frame) and therefore power consumption is increased by a factor of N. On the other hand, the operation frequency is decreased by N and therefore power consumption is reduced by N2. In total, the power consumption is reduced by N2−N. In this case the storage for N samples is required. All of the locations in the storage 304 should be readable in parallel. The frame size (i.e., the storage size) N is decided by how much of a power reduction is desired.

All of the samples for a frame are read in parallel from the storage 304 and sent to CIC filter 306. The CIC filter 306 performs filtering of the samples in the frame in parallel. The operations may be spread across multiple processing elements, such as across multiple cores, processors or logic elements, like adders or multipliers. Partial results may be generated as part of the parallel processing and combined to generate a final result. Each parallel processing path for each sample may be independent and may generate an independent partial result, as will be described below for some examples. The output of the CIC filter 306 can be filtered by a CIC compensation filter 308 that compensates for some of the shortcomings of the CIC filter 306. The output of the CIC compensation filter 308 is then passed to further digital processing 310.

With the advent of Giga samples per second ADCs that can sample an analog signal up to 3.7 Giga sample per second or more, it is now possible to perform RF sampling rather than IF (intermediate frequency) or baseband frequency sampling. The benefit of RF sampling at Giga samples per second is that the RF sampling can solve today's integration challenges. The RF sampling can replace IF sampling, mixer, amplifier, filters and the like in the analog domain and bring those components into the digital domain and therefore reduce costs, design time, circuit board size, weight, and power.

The digital processing logic 108 may take many forms as depicted in FIG. 3B. The digital processing logic may be a central processing unit (CPU) 332 or a graphical processing unit (GPU) 338. The digital processing logic 108 may be a field programmable gate array (FPGA) 334 or an application specific integrated circuit (ASIC) 336. The digital processing logic 108 may be a digital signal processing (DSP) chip 340. The digital processing logic 108 may in some embodiments include a combination of these components. For example, a CPU and a GPU may work together, with the GPU on a graphics card. In addition, the processing logic 108 may include multiple processing elements, such as multiple cores or multiple processors.

Where the environment 100 is realized in software, the displayed components may be realized in software. For example, if the environment is realized as a simulatable model, the components of the environment 100 may be realized by interconnected model components such as blocks that perform the functionalities of the corresponding devices in a model simulation environment.

The digital processing 108 hardware may operate at a slower megahertz rate than the ADC 106 sampling rate. Thus, the filter with the recursive transfer function may be limited to operate at the lower speed of the digital processing hardware 108 versus the sampling rate of the ADC 106. By making the filter with the recursive transfer function frame-based and capable of processing frames with more than one sample per cycle, the exemplary embodiments can significantly increase the throughput of the filter. The filter may, for instance, receive a frame of samples containing samples for five consecutive sampling times. For example, if the filter can process a frame per cycle and the frame contains five samples, the throughput of the filter may be increased five-fold. As a result, the filtering may keep pace with the sampling rate of the ADC 106. By enabling more samples to be filtered, the resulting filtered output samples may be of a higher resolution and hence provide a higher accuracy of the input. Another benefit is that there are lower memory requirements with the parallel implementations of the filters described herein than the conventional serial filters.

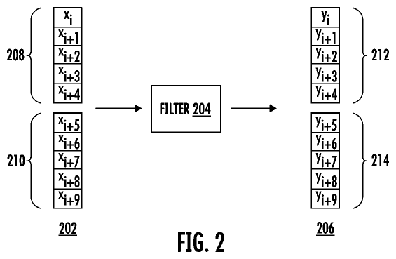

FIG. 2 illustrates an example of frame-based filtering where each frame contains input samples of data values from a common source, e.g., a signal source, an image source, an audio source, a radar source, a satellite source, a GPS source, a seismic data source, or a source of time series data for multiple consecutive sampling times. The input samples 202 are to be filtered by filter 204 to produce output 206. The filter 204 has a recursive transfer function. In this example, in one filtering cycle the filter 204 receives a frame 208 of input samples 208 (xᵢ to xᵢ₊₄) and produces a frame 212 of filtered output samples (yᵢ to yᵢ₊₄) as outputs, where i represents an index of sample time, xᵢ represents the input sample x at sample time i, and yᵢ represents the output sample for sample time i. In the next cycle, frame 210 of inputs containing a next frame of samples and produces an output frame 214 of consecutive samples.

The frame size can be determined by many factors, for example the digital processing speed/frequency, power consumption, and/or processing resource usage (hardware/filter availability).

A frame, for example, may contain samples of digital data from a time varying signal (i.e., a signal with a value that varies over time). As another example, a frame may contain sampled data in the form of color values for adjacent pixels of an image at consecutive sampling times.

Each input sample need not contain a single data value but may contain multiple data values. For example, suppose that the data being sampled is RGB values for a given pixel in an image. Thus, for a frame containing two input samples, a first input sample may contain the red, green and blue values for the pixel at a first sample time and the second input sample may contain the red, green, and blue values for the same pixel at a next sample time.

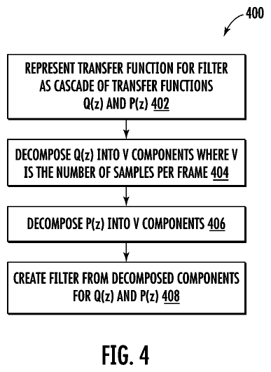

FIG. 4 depicts a flowchart 400 of example steps that may be performed to realize a parallel implementation of a filter with a recursive transfer function so that the filter can process multiple samples of a frame in parallel, e.g., CIC filter 306 as described in connection with FIG. 3. The transfer function of the filter may be expressed as a cascade of transfer functions Q(z) and P(z) (402), where z is a value in the Z domain. The Z domain is a complex domain also known as the complex frequency domain, consisting of real axis (x-axis) and imaginary axis (y-axis). A signal may be defined as a sequence of real or complex numbers which is then converted to the Z domain by the process of z transform. After the transfer function of the filter is represented in this manner, polyphase decomposition can be performed to decompose Q(z) into V components (404), where V is the number of samples in the frame that is input to filter. For example, V is 5 in the example shown in FIG. 2. Each component produces an output for a corresponding input sample in the frame. Similarly, polyphase decomposition is performed to decompose the transfer function P(z) into V components (406). Examples of how the polyphase decomposition is performed for the transfer functions will be described below for example filter types having recursive transfer functions. The decomposed components for Q(z) and P(z) are then combined to create a filter to filter a frame of input samples as will be described in more detail.

The filter may be realized in hardware, in software or in a combination thereof. When realized in software, the software may perform functionalities of a filter by filtering real world, measured or acquired sample data values imported into a software environment or may filter simulated sample data values. In some embodiments the filtering may be performed by one or more components of a simulatable or executable model in a simulation environment. The filter may be a hardware device that performs filtering by executing code generated from such models or independent of models.

One type of filter having a recursive transfer function to which the approach of FIG. 4 may be applied to produce a parallel implementation is a CIC filter. FIG. 5A depicts an example of a CIC filter 500 have a single integrator stage 502 and a single comb filter stage 504 that receives a single input sample x(n) and produces a single filtered output sample y(n, where n is the sample time index, x(n) is the input sample at sample time n and y(n) is the filtered output sample for sample time n. The integrator stage 502 contains an adder 506 and a delay 508. The delay 508 delays the output of the adder 506 by one cycle and adds that value to x(n). Consider the case of x(3). The adder initially adds 0 to x(1). In the next cycle, the adder 506 adds x(1) to x(2) to yield (x(1)+x(2)). In the next cycle, (x(1)+x(2)) is added to x(3). In this fashion, the integrator stage 502 integrates the input values. The comb stage has a subtractor 510 and a delay 512. It produces filtering by subtracting previous input value from a current input value. The delay 512 delays the input by q cycles of the comb stage (where q is an integer), where each cycle in this context is the period of time is takes for the comb stage to process an input into a filtered output Hence, the input value at sampling time (n−q) is subtracted from the input at sampling time (n).

In applying, the approach of FIG. 4 to a CIC filter, the transfer function for the CIC filter H(z) may be expressed in terms of cascaded transfer functions Q(z) and P(z) (402). In particular, the transfer function may be expressed as H(z)=P(z)*Q(z) equation 1, where

$$P ( z ) = {b}_{0} + {b}_{1} {z}^{- 1} + {b}_{2} {z}^{- 2} + \text{…} + {b}_{n} {z}^{- n} and Q ( z ) = \frac{1}{1 + {a}_{1} {z}^{- 1} + {a}_{2} {z}^{- 2} + \text{…} + {a}_{m} {z}^{- m}} = \frac{1}{L ( z )} ,$$

where n and m represent the polynomial order of P(z) and Q(z), z is the input in the z domain and z⁻¹ indicates a unit delay. For the CIC filter, Q(z) is the transfer function of the integrator stage 502. This transfer function for the integrator stage may be expressed as

$$Q ( Zz ) = \frac{1}{1 - {z}^{- 1}} .$$

Polyphase decomposition may then be applied to this transfer function to yield V phase components, where V is the number of samples in a frame. As an example, the decomposition will be derived for a frame size of two, with the two samples being from adjacent sampling times. For any linear time invariant (LTI) system, the output of the system can be expressed as:

Y(z)=H(z)·X(z) Equation 2

Where H(z) is the transfer function in the z domain of a linear time invariant system (LTI), Y(z) is the output of the LTI system in the z domain and X(z) is the input to the LTI system in the Z domain. H(z) may be decomposed into two polyphase parts, X₂ₖ and Y₂ₖ are even samples, and X₂ₖ₊₁ and Y₂ₖ₊₁ are odd:

X(z)=X₀(z²)+z⁻¹X₁(z²) Equation 3

H(z)=H₀(z²)+z⁻¹H₁(z²) Equation 4

Y(z)=Y₀(z²)+z⁻¹Y₁(z²) Equation 5

Thus, the output may be expressed as:

$$Y ( z ) = H ( z ) . X ( z ) = {X}_{0} ( {z}^{2} ) {H}_{0} ( {z}^{2} ) + {z}^{- 1} [ {X}_{0} ( {z}^{2} ) {H}_{1} ( {z}^{2} ) + {X}_{1} ( {z}^{2} ) {H}_{0} ( {z}^{2} ) ] + {z}^{- 2} {X}_{1} ( {z}^{2} ) {H}_{1} ( {z}^{2} ) \qquad Equation 6$$

The odd and even samples (i.e., terms with odd indexed sampling times and terms with even indexed sampling times) in the expanded expression of Equation 6 (e.g., X₀(z²)H₀(z²)+z⁻¹ [X₀(z²)H₁ (z²)+X₁(z²)H₀(z²)]+z⁻²(z²)H₁ (z²)) may then be separated by down sampling by two and by applying noble identity for the down sampling. Using noble identity decreases the order of H(z²) to H(z) by moving the down sampling operation from output to the input. Note that Y₀ and Y₁ are down sampled samples of Y and that X₀ and X₁ are down-sampled samples of X. As a result, the two parts of the output in equation 5 may be expressed as

Y₀(z)=X₀(z)H₀(z)+z⁻¹X₁(z)H₁(z) Equation 7

Y₁(z)=X₀(z)H₁(z)+(z)H₀(z) Equation 8

Since the parts of the output of Equation 6 are separated, Y₁(z) is delayed by one cycle with respect to Y₀(z). Therefore z⁻¹ in front of z⁻¹[X₀(z²)H₁(z²)+(z²)H₀ (z²)] is eliminated. Also z⁻² is reduced to z⁻¹ due to applying down sampling noble identity.

This can be expressed in matrix form as:

$$⌈ \begin{matrix}{Y}_{0} \\ {Y}_{1}\end{matrix} ⌉ = [ \begin{matrix}{H}_{0} ( z ) & {z}^{- 1} {H}_{1} ( z ) \\ {H}_{1} ( z ) & {H}_{0} ( z )\end{matrix} ] \cdot ⌈ \begin{matrix}{X}_{0} \\ {X}_{1}\end{matrix} ⌉ \qquad Equation 9$$

A similar process may be performed for when the frame size v is a value greater than 2. In that case, Y(z)=H(z).X (z) may be in terms of Xᵥ(z) and Hᵥ(z) as:

X(Z)=X₀(z^{v})+z⁻¹X₁(z^{v})+z⁻²X₂(z^{v})+ . . . +z^{-(v-1)}Xᵥ₋₁(z^{v}) Equation 10

H(z)=H₀(z^{v})+z⁻¹H₁(z^{v})+z⁻²H₂(z^{v})+ . . . +z^{-(v-1)}Hᵥ₋₁(z^{v}) Equation 11

Y(z)=Y₀(z^{v})+z⁻¹Y₁(z^{v})+z⁻²Y₂(z^{v})+ . . . +z^{-(v-1)}Yᵥ₋₁(z^{v}) Equation 12

After substituting X(z) and H(z) in Y(z)=H(z).X(z) then Y(z) can be written in matrix form after applying down sampling noble identity:

$$\begin{matrix} & Equation 13 \\ ⌈ \begin{matrix}{Y}_{0} \\ {Y}_{1} \\ … \\ {Y}_{v - 2} \\ {Y}_{v - 1}\end{matrix} ⌉ = [ \begin{matrix}{H}_{0} & {z}^{- 1} {H}_{v - 1} & {z}^{- 1} {H}_{v - 2} & … & … & {z}^{- 1} {H}_{1} \\ {H}_{1} & {H}_{0} & {z}^{- 1} {H}_{v - 1} & {z}^{- 1} {H}_{v - 2} & … & {z}^{- 1} {H}_{2} \\ … & … & … & … & … & … \\ {H}_{v - 2} & {H}_{v - 3} & {H}_{v - 4} & … & … & {z}^{- 1} {H}_{v - 1} \\ {H}_{v - 1} & {H}_{v - 2} & {H}_{v - 3} & {H}_{v - 4} & … & {H}_{0}\end{matrix} ] \cdot ⌈ \begin{matrix}{X}_{0} \\ {X}_{1} \\ … \\ {X}_{v - 2} \\ {X}_{v - 1}\end{matrix} ⌉ . & \end{matrix}$$

It is helpful to determine how to decompose transfer functions of the form

$$H ( z ) = \frac{1}{1 - {az}^{- 1}} .$$

As will be explained below, an integrator has a transfer function of this form, where a=1.
First, a Taylor series expansion of H(z) may be performed because this will yield a polynomial with a known decomposition. The expansion is:

$$W ( z ) = Taylor ( H ( z ) ) = - \frac{1}{a} z - \frac{1}{{a}^{2}} {z}^{2} - \frac{1}{{a}^{3}} {z}^{3} - \frac{1}{{a}^{4}} {z}^{4} - \frac{1}{{a}^{5}} {z}^{5} \qquad Equation 14$$

This represents an infinite tap finite impulse response (FIR) filter. W(z) may be decomposed into two parts as:

$$\begin{matrix} W ( z ) = {W}_{0} ( {z}^{2} ) + {z}^{- 1} {W}_{1} ( {z}^{2} ) \\ Where & Equation 15 \\ {W}_{0} ( {z}^{2} ) = - \frac{1}{{a}^{2}} {z}^{2} - \frac{1}{{a}^{4}} {z}^{4} - \frac{1}{{a}^{6}} {z}^{6} … = \frac{1}{1 - {a}^{2} {z}^{- 2}} = {H}_{0} ( {z}^{- 2} ) & Equation 16 \\ {W}_{1} ( {z}^{2} ) = a [ - \frac{1}{{a}^{2}} {z}^{2} - \frac{1}{{a}^{4}} {z}^{4} - \frac{1}{{a}^{6}} {z}^{6} \text{…} ] = \frac{a}{1 - {a}^{2} {z}^{- 2}} = {H}_{1} ( {z}^{- 2} ) & Equation 17\end{matrix}$$

Hence, the equation 11 for H(z) may be rewritten as:

H(z)=H₀(z²)+z⁻¹H₁(z²) Equation 18

This is for the case where the frame size v is 2. We can express the decomposition for v being any size greater than 2. As described above, the Taylor expansion can be applied.

Per Equation 14, the Taylor expansion of H(z) is:

$$W ( z ) = Taylor ( H ( z ) ) = - \frac{1}{a} z - \frac{1}{{a}^{2}} {z}^{2} - \frac{1}{{a}^{3}} {z}^{3} - \frac{1}{{a}^{4}} {z}^{4} - \frac{1}{{a}^{5}} {z}^{5}$$

Decompose W(z) into W₀(z), W₁(z) . . . Wᵥ₋₁(z) where v is the input vector size.

$$\begin{matrix}{W}_{0} ( {z}^{v} ) = - \frac{1}{{a}^{v}} {z}^{v} - \frac{1}{{a}^{2 v}} {z}^{2 v} - \frac{1}{{a}^{3 v}} {z}^{3 v} & Equation 19 \\ {W}_{1} ( {z}^{v} ) = {az}^{- 1} [ - \frac{1}{{a}^{v}} {z}^{v} - \frac{1}{{a}^{2 v}} {z}^{2 v} - \frac{1}{{a}^{3 v}} {z}^{3 v} … ] = {az}^{- 1} {W}_{0} ( {z}^{v} ) & Equation 20 \\ {W}_{v - 1} ( {z}^{v} ) = {a}^{v - 1} {z}^{- ( v - 1 )} [ - \frac{1}{{a}^{v}} {z}^{v} - \frac{1}{{a}^{2 v}} {z}^{2 v} - \frac{1}{{a}^{3 v}} {z}^{3 v} … ] = {a}^{v - 1} {z}^{- ( v - 1 )} {W}_{0} ( {z}^{v} ) . & Equation 21\end{matrix}$$

### Then:

W(z)=W₀(z^{v})Σₙ₌₀^{v-1}a⁻ⁿz⁻ⁿ Equation 22

### However:

$${W}_{0} ( {z}^{v} ) = - \frac{1}{{a}^{v}} {z}^{v} - \frac{1}{{a}^{2 v}} {z}^{2 v} - \frac{1}{{a}^{3 v}} {z}^{3 v} … = \frac{1}{1 - {a}^{v} {z}^{- v}} = {H}_{0} ( {z}^{- v} ) \qquad Equation 23$$

Therefore H(z) can written as:

H(z)=H₀(z^{v})Σₙ₌₀^{v-1}a⁻ⁿz⁻ⁿ Equation 24

Then, the decomposition of H(z) is:

$$\begin{matrix}{H}_{0} ( {z}^{- v} ) = \frac{1}{1 - {a}^{v} {z}^{- v}} & Equation 25 \\ {H}_{1} ( {z}^{- v} ) = a {H}_{0} ( {z}^{- v} ) & Equation 26 \\ {H}_{2} ( {z}^{- v} ) = {a}^{2} {H}_{0} ( {z}^{- v} ) & Equation 27 \\ … & \\ \begin{matrix}{H}_{v - 1} ( {z}^{- v} ) = {a}^{v - 1} {H}_{0} ( {z}^{- v} ) & \end{matrix} & Equation 28\end{matrix}$$

The above-derived matrix expression (see Equation 9) for the output of a linear time invariant system can be applied to the integrator as the integrator is a linear time invariant system. to yield the expression of the transfer function of the integrator as:

$$⌈ \begin{matrix}{Y}_{0} \\ {Y}_{1}\end{matrix} ⌉ = [ \begin{matrix}{Q}_{0} & {z}^{- 1} {Q}_{1} \\ {Q}_{1} & {Q}_{0}\end{matrix} ] \cdot ⌈ \begin{matrix}{X}_{0} \\ {X}_{1}\end{matrix} ⌉ \qquad Equation 29$$

For the integrator transfer function

$$Q ( z ) = \frac{1}{1 - {z}^{- 1}} .$$

Equation 9 can be applied where a=1 to yield the expression of the outputs for the frame-based integrator as:

$$⌈ \begin{matrix}{Y}_{0} \\ {Y}_{1}\end{matrix} ⌉ = Q [ \begin{matrix}1 & {z}^{- 1} \\ 1 & 1\end{matrix} ] \cdot ⌈ \begin{matrix}{X}_{0} \\ {X}_{1}\end{matrix} ⌉ \qquad Equation 30$$

The P(z) of the cascaded transfer functions for the CIC filter is the transfer function for the comb filter portion of equation 1. The comb filter stage of the CIC frame-based filter has a transfer function of P(z)=1−z^{-m}. The comb filter stage may be treated as a FIR filter, and since the FIR filter is an LTI system, the transfer function for the comb filter stage may be decomposed using the approach of decomposing the transfer function in a polynomial form described above relative to equations 1-9 accordingly (step 406). In particular, for a frame size of two input samples of data values, the transfer function is decomposed by two into H₀(z) being the part for even terms and H₁(z) being the part for the odd terms. More generally, for N samples per frame, the transfer function is decomposed by N, where N is an integer. Equations 7 and 8 may be used to express the outputs Y₀ and Y₁ in terms of the transfer functions H₀ and H₁ and the inputs X₀ and X₁ for the comb filter stage.

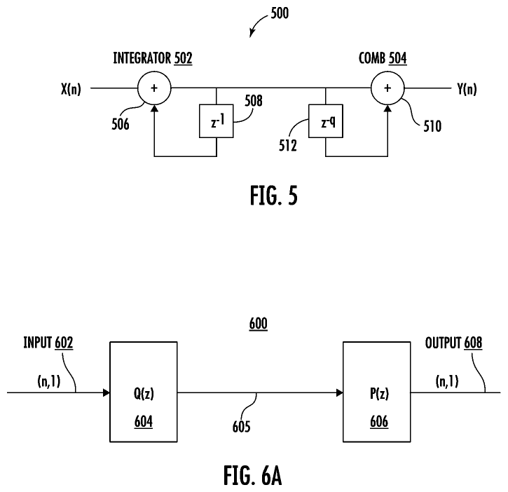

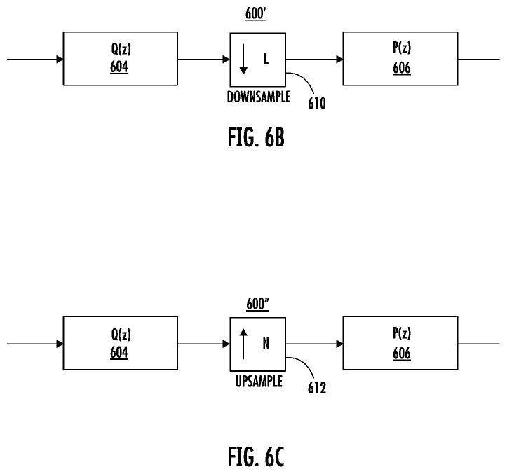

In (408) the decomposed components, e.g., the equations expressing outputs Y₀ and Y₁ in terms of transfer functions H₀ and H₁ and inputs X₀ and X₁, are used to build an implementation of the filter. In some embodiments the implementation is realized in a model. One such model is a simulatable or executable model, such as a block diagram model. The model may be built and simulated in a simulation environment. FIG. 6A depicts a high-level model for a filter, e.g., a CIC filter, that has a transfer function that may be expressed as cascaded transfer functions Q(z) and P(z) in the model 600 of FIG. 6A. As shown in FIG. 6A, a frame of input samples 602 is input to a block 604 that applies the transfer function Q(z) to yield output 605. The output 605 is input to block 606, which applies the transfer function P(z) to the input. The filtered output samples 608 are then output as a frame of output samples.

CIC filters may be reducing (e.g., decimating) in that they may down sample. FIG. 6B shows a model 600′ of such a decimating CIC filter. The model 600′ is the same as the model 600 and includes blocks 604 and 606 arranged in cascaded fashion except that the model 600′ includes a down sampling component 610 for performing down sampling on the samples output from block 604. Such decimating CIC filters may be useful in applications, such as in a signal receiver like those described above where sampling rates of incoming data are at a high frequency and need to be reduced at the receiver.

Alternatively, CIC filters may be interpolating. Such CIC filters up sample. FIG. 6C shows a model 600″ for an interpolating CIC filter. Model 600″ is like model 600′ with blocks 604 and 606 arranged in the same cascaded fashion but the down sampling component 610 is replaced with an up sampling component 612. Such interpolating components can be useful in applications, such as in a signal transmitter like those described above where sampling rates of outgoing data are low and need to be increased at the transmitter.

The down sampling components (e.g., 610) and the up sampling components (e.g., 612) alternatively to what is shown in FIGS. 6B and 6C may be located before the integrator stage or after the comb stage. Moreover, a CIC filter may include multiple integrator stages and multiple comb stages.

The presence of a down sampling component (e.g., 610) or an up sampling component (e.g., 612) in a CIC filter does not change the polyphase decomposition for such a CIC filter. However, in instances where the filter is modeled, such as in a simulation environment, the down sampling components and the up sampling components may be included in the models.

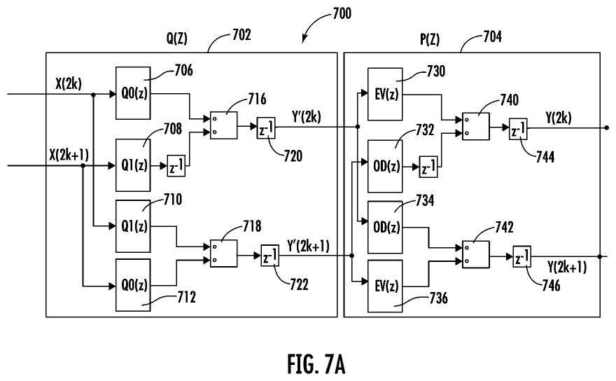

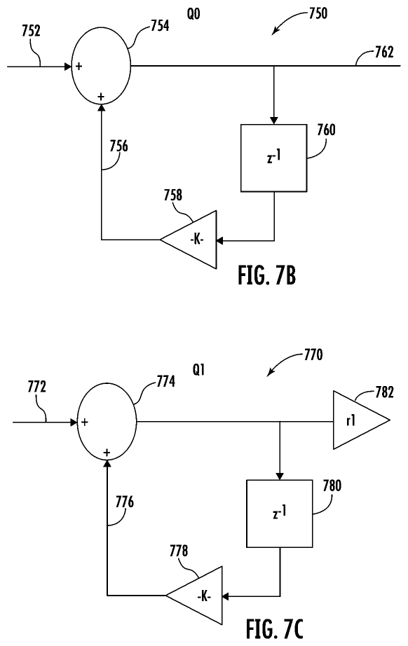

FIG. 7A depicts a more detailed model 700 of high-level model 600 of FIG. 6A. The model 700 includes a subsystem 702 representing the functionalities of Q(z) and a subsystem 704 representing the functionalities of P(z). In this example, the Q(z) subsystem 702 includes inputs X(2k) and X(2k+1) for each frame These are input samples taken at sampling time points 2k and 2k+1, respectively, where k is a sampling time index that is associated with a particular sampling time and 2k+1 represents the next sampling time index value. As discussed above, the outputs Y₀ and Y₁ in the z domain can be expressed as:

Y₀(z)=X₀(z)Q₀(z)+z⁻¹X₁(z)Q₁(z)

Y₁(z)=X₀(z)Q₁(z)+X₁(z)Q₀(z)

In the example shown in FIG. 7A, block 706 performs the functionalities of the transfer function Q₀(z) on input X₀(z), which represents X(2k). Block 708 performs the transfer function Q₁(z) on input X₁(z), which represents X(2k+1). Delay block 714 applies a delay on X₁(z)Q₁(z) by one cycle. Adder block 716 adds X₀(z)Q₀(z) and z⁻¹X₁(z)Q₁(z) to get the output Y₀(z), designated as Y(2k). Block 710 performs the transfer function Q₁(z) on input X₀(z). Block 712 performs the transfer function Q₀(z) on the input X₁(z). Adder 718 adds X₀(z)Q₁(z) and X₁(z)Q₀(z) to get the output Y₁(z), designated as Y(2k+1). Delays 720 and 722 are applied at the outputs Y′(2k) and Y′(2k+1).

FIG. 7B shows a model 750 of the Q₀ transfer function block (e.g., blocks 706 and 712 in FIG. 7A). The input to the block 752 is added to the fed back output 756 from block 758, which is a multiply block that multiplies by K. The input of the block 758 is the output of the adder 754 delayed by a cycle by delay block 760. The output of the adder 754 is the output 762 for the Q₀ transfer function block.

FIG. 7C shows a model 750 of the Q₁ transfer function block (e.g., blocks 708 and 710 in FIG. 7A). The input to the block 772 is added by adder 774 to the fed back output 776 from block 778, which is a multiply block that multiplies by K. The input of the block 778 is the output of the adder 774 delayed by a cycle by delay block 780. The output of the adder 774 is fed to block 782, which is a multiply block that multiplies by r₁. The output of block 782 is the output 762 for the Q₀ transfer function block.

The decomposition of P(z) can be achieved as reflected in FIG. 7A. In this example, block 730 performs the functionalities of the even transform EV(z) (see H₀ (z) in equation 9) on the input (i.e., Y(2k)=Y_{2K}(z) delayed by a cycle) which can be thought of as X₀(z), to yield X₀(z)H₀(z), and block 732 performs the odd transform (i.e., H₁(z) in equation 9) on the second input (i.e., Y(2k+1) delayed by a cycle), which can be thought of as X₁ (z). A delay block applies a delay to the output of block 732 of a cycle to produce z⁻¹X₁(z)H₁(z). Adder block 740 adds X₀(z)H₀(z) and z⁻¹X₁(z)H₁(z) to yield the output Y₀(z), designated as Y(2k) (see equation 9). Block 734 performs the odd transform (i.e., H₁(z)) on input Y₂ₖ(Z) delayed by a cycle (i.e., X₀(z)) to yield X₀(z)H₁(z). Block 736 performs the even transform (i.e., H₀(z)) on the second input (i.e., X₁(z)) to yield X₁(z)H₀ (z). Adder block 742 adds X₀(z)H₁(z) and X₁(z)H₀(z) to produce the output Y₂ₖ₊₁(z), (see Y₁(z) in equation 9). Delay blocks 744 and 746 are provided for the outputs.

As can be seen in FIG. 7A, each parallel partition may require an adder or two or a multiplier or two. The components needed is driven by the decomposition of the transfer function as expressed in the equations for the outputs. In general, the components required per parallel partition are not expensive and can perform their associated operations quickly.

The polyphase decomposition may also be used to produce a frame-based biquad filter. For a biquad filter, the transfer function is of the form

$$H ( z ) = Q ( z ) * P ( z ) where P ( z ) = {b}_{0} + {b}_{1} {z}^{- 1} + {b}_{2} {z}^{- 2} and Q ( z ) = \frac{1}{1 + {a}_{1} {z}^{- 1} + {a}_{2} {z}^{- 2}} . \qquad Equation 31$$

P(z) of equation 31 for the biquad filter is the transfer function for a FIR filter and the polyphase decomposition for an LTI system as explained relative to equations 1-9 can be used.

In this example, H(z) (see equation 17) can be decomposed into polyphase components (i.e., two components in this example). Q(z) can be written in the form of

$$Q ( z ) = \frac{1}{( 1 - {r}_{1} {z}^{- 1} ) ( 1 - {r}_{2} {z}^{- 1} )} , \qquad Equation 32$$

where r₁, r₂ are the poles of Q(z). Then, Q(z) an be written as

$$Q ( z ) = W ( z ) V ( z ) where W ( z ) = \frac{1}{( 1 - {r}_{1} {z}^{- 1} )} and V ( z ) = \frac{1}{( 1 - {r}_{2} {z}^{- 1} )} . \qquad Equation 33$$

By using equation 20 for expressing the outputs Y₀ and Y₁, Q(z) for frames of two input samples results in:

$$⌈ \begin{matrix}{Y}_{0} \\ {Y}_{1}\end{matrix} ⌉ = [ \begin{matrix}{W}_{0} & {z}^{- 1} {W}_{1} \\ {W}_{1} & {W}_{0}\end{matrix} ] \cdot [ \begin{matrix}{V}_{0} & {z}^{- 1} {V}_{1} \\ {V}_{1} & {V}_{0}\end{matrix} ] ⌈ \begin{matrix}{X}_{0} \\ {X}_{1}\end{matrix} ⌉ \qquad Equation 34$$

### Where:

$$\begin{matrix}{W}_{0} ( z ) = \frac{1}{1 - {{r}_{1}}^{2} {z}^{- 1}} & Equation 35 \\ {W}_{1} ( z ) = \frac{{r}_{1}}{1 - {{r}_{1}}^{2} {z}^{- 1}} & Equation 36 \\ {V}_{0} ( z ) = \frac{1}{1 - {{r}_{2}}^{2} {z}^{- 1}} & Equation 37 \\ {V}_{1} ( z ) = \frac{{r}_{2}}{1 - {{r}_{2}}^{2} {z}^{- 1}} & Equation 38\end{matrix}$$

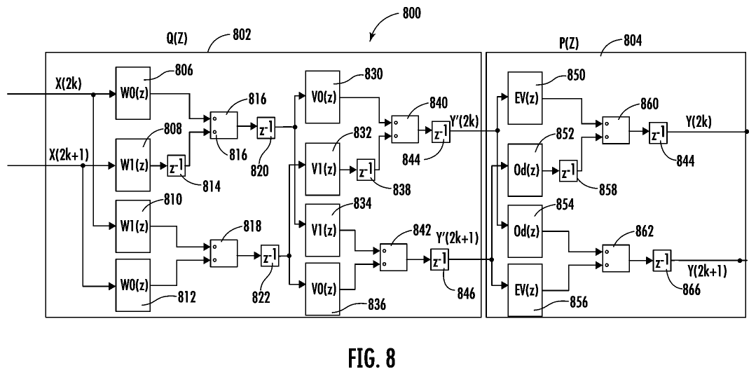

Like the CIC filter, a model may be built for implementing the biquad filter. The model may be simulatable in a simulation environment. FIG. 8 depicts a model 800 for a biquad filter that processes frames of two input samples. The model includes a subsystem 802 representing the transfer function Q(z) and a subsystem 804 representing the transfer function P(z). The subsystem 802 receives inputs X(2k) and X(2k+1) for sample times 2k and 2k+1. Blocks 806 and 812 perform transform W₀(z) with respective inputs, and blocks 808 and 810 perform transform W₁(z) with respective inputs. A delay block 814 applies a delay of one cycle to the output of block 808. Adders 816 and 818 add their inputs. The outputs of adders 816 and 818 are delayed a cycle by respective delay blocks 820 and 822.

Blocks 830 and 836 perform transform V₀(x) for respective inputs and blocks 832 and 834 perform transform V₁(x) for respective inputs. A delay block 838 delays the output of block 832 by one cycle. Adder blocks 840 and 842 add their inputs. The outputs of adder blocks 840 and 842 are delayed a cycle by delay blocks 844 and 846.

The result of the components of Q(z) is that the outputs are as:

$$⌈ \begin{matrix}{Y}_{0} \\ {Y}_{1}\end{matrix} ⌉ = [ \begin{matrix}{W}_{0} & {z}^{- 1} {W}_{1} \\ {W}_{1} & {W}_{0}\end{matrix} ] \cdot [ \begin{matrix}{V}_{0} & {z}^{- 1} {V}_{1} \\ {V}_{1} & {V}_{0}\end{matrix} ] ⌈ \begin{matrix}{X}_{0} \\ {X}_{1}\end{matrix} ⌉ \qquad Equation 39$$

As mentioned above P(z) of equation 31 for the biquad filter is the transfer function for a FIR filter and the polyphase decomposition for an LTI system as explained relative to equations 1-9 can be used. Hence, the resulting representation in FIG. 8 is like that of FIG. 7A. Block 850 performs the even transform EV(z) on the input, and block 852 performs the odd transform OD(z) on the second input. A delay block 858 applies a delay of one cycle to the output of block 852. Adder block 860 adds the output from block 850 and the delayed output from block 852 to produce an output. Block 854 performs the odd transform on the first input. Block 856 performs the even transform on the second input. Adder block 862 adds the outputs of blocks 854 and 856 to produce an output. The outputs of adder blocks 860 and 862 may be subject to delays for timing purposes by respective delay blocks 864 and 866.

The polyphase decomposition approach described herein with respect to FIG. 4 may also be applied to IIR filters to make the IIR filters frame filters that may handle more than one input sample, e.g., in parallel, per cycle. The transfer function of an IIR filter may be expressed as

$$H ( z ) = Q ( z ) * P ( z ) \\ where \\ P ( z ) = {b}_{0} + {b}_{1} {z}^{- 1} + {b}_{2} {z}^{- 2} + … + {b}_{n} {z}^{- n} and Q ( z ) = \frac{1}{1 + {a}_{1} {z}^{- 1} + {a}_{2} {z}^{- 2} + … + {a}_{m} {z}^{- m}} ( step 402 )$$

where n and m are integers specifying polynomial order. Q(z) can be rewritten as:

$$Q ( z ) = \frac{1}{1 + {a}_{1} {z}^{- 1} + {a}_{2} {z}^{- 2} + … + {a}_{m} {z}^{- m}} = \frac{1}{( 1 - {r}_{1} {z}^{- 1} )} * \frac{1}{( 1 - {r}_{2} {z}^{- 21} )} * … \frac{1}{( 1 - {r}_{1 m} {z}^{- 1} )}$$

where r₁, r₂, . . . , rₘ are the poles of Q(z). Then the general solution for

$$Q ( z ) = \frac{1}{1 - a {z}^{- 1}}$$

can be applied as described above relative to equations 10-15, with a=r₁, r₂, . . . rₘ. Thus, H(z) is decomposed (step 404).

Pₙ(z) is a FIR filter of order n and the polyphase decomposition for such a FIR filter described above can be used (step 406). The resulting components of H(z) and P(z) may be used to implement the IIR filter (step 408).

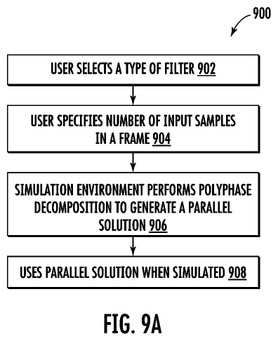

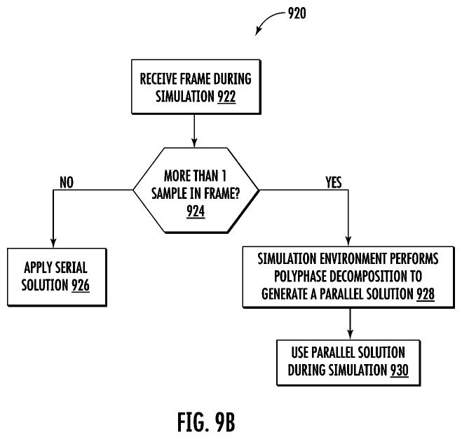

The frame filters described herein may handle frames of size one or of sizes greater than one. FIG. 9 provides a flowchart 900 of steps that may be performed for the different cases. In step 902, the filter may check whether more than one input sample is to be processed per cycle (i.e., does the frame contain more than one cycle). If there is only one input sample to be processed per cycle (i.e., a frame of one input sample), a serial approach may be used. The samples may be processed in serial manner one per cycle. If there are more than two input samples per frame such that more than 1 input sample is to be processed per cycle, a parallel approach like those described above that use polyphase decomposition may be used (904). Thus, if the implementation is realized in a model a block or subsystem may receive frames of input sample of different sizes and use a serial approach or a parallel approach as warranted.

As was mentioned above, the implementation of the filter may be realized in a model and code may be generated from the model to implement the filter on target hardware. The model may perform the polyphase decomposition of the recursive filter function as has been described above for filters that processes a frame with multiple input samples. The polyphase composition may be performed before the model is simulated or during the simulation in some instances. FIG. 9A depicts a flowchart 900 of steps that may be performed when the polyphase decomposition is performed before simulation. In this instance, the user selects a type of filter (902) with a recursive transfer function (e.g., CIC filter, biquad filter, or other type of IIR filter). The user then may specify the number of input samples for the frame (i.e., an integer value greater than 1) (904). The user may make the selection of the filter type and the specification of the number of input samples in a frame via a user interface or programmatically in some instances. The simulation environment then performs the polyphase decomposition to generate a parallel solution for the decomposition of the recursive filter function (906). When the model is simulated, the parallel solution is used for the simulation. For instance, models like model 700 in FIG. 7 and model 800 in FIG. 8 may be used.

In other instances, the polyphase decomposition may be performed during simulation of the model. FIG. 9B illustrates of flowchart 920 of illustrative steps that may be performed in such an instance. For this example, the filter can accept input frames with one or more input samples. Based on the input, the filter provides either a serial implementation or a parallel implementation. The filter receives a frame as input during the simulation (922). The filter receives the frame and checks whether there are more than 1 input samples in the frame (924). If there is only one input sample, a serial solution of processing one sample at a time is used (926) (e.g., the serial solution for a CIC shown in FIG. 5), where one input sample is processed per cycle. If the frame contains more than one input sample, then a polyphase decomposition of the recursive transfer function is performed to produce a decomposition suitable for the number of input samples (928). A parallel solution using the decomposition as described above is used (930).

The models of the filters enable the behavior of the filters to be simulated. This simulation is helpful in understanding the behavior of the filters and designing such filters. The models also help in understanding the behavior of systems and devices where the filters are deployed, such as transmitters/receivers, and the like as discussed above.

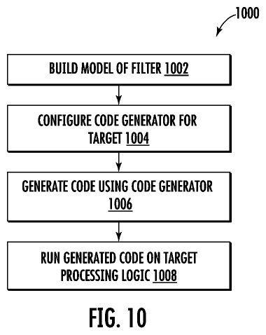

Code may be generated from the models. The code is programming language code that performs the functionality of the filter to provide a parallel implementation. FIG. 10 provides a flowchart of the steps that may be performed for such code generation. Initially, a model of the filter is built (1002). The model may be realized in programming language code or may be realized in a model development environment, such as a model simulation environment. The model development environment may enable the development of graphical models, like block diagram models. The illustrative models depicted in FIGS. 5-8 are Simulink® block diagram models developed in the Simulink model development environment from The MathWorks Inc. of Natick Mass. Other exemplary simulation and modeling environments that may be used for the exemplary embodiments include the MATLAB® algorithm development environment from The MathWorks, Inc., as well as the Simscape™ physical modeling tool and the Stateflow® state chart tool also from The MathWorks, Inc., the MapleSim physical modeling and simulation tool from Waterloo Maple Inc. of Waterloo, Ontario, Canada, the LabVIEW virtual instrument programming system and the NI MatrixX model-based design product both from National Instruments Corp. of Austin, Tex., the Visual Engineering Environment (VEE) from Keysight Technologies, Inc. of Santa Clara, Calif., the System Studio model-based signal processing algorithm design and analysis tool and the SPW signal processing algorithm tool from Synopsys, Inc. of Mountain View, Calif., a Unified Modeling Language (UML) system, a Systems Modeling Language (SysML) system, the System Generator system from Xilinx, Inc. of San Jose, Calif., and the Rational Rhapsody Design Manager software from IBM Corp. of Somers, N.Y. Models created in the high-level simulation environment may contain less implementation detail, and thus operate at a higher level than certain programming languages, such as the C, C++, C#, and SystemC programming languages.

A code generator may be provided for generating code from the model. The code generated may be configurable for running on particular target hardware. Thus, it may be necessary to configure the code generation process for the particular target hardware (1004). The target hardware may be processing logic like a CPU, GPU, a FPGA, an ASIC or the like. Code is generated from the model using a code generator (1006). Exemplary code generators include, but are not limited to, the Simulink® Coder™, the Embedded Coder®, and the HDL Coder™ products from The MathWorks, Inc. of Natick, Mass., and the TargetLink product from dSpace GmbH of Paderborn Germany. The code may then be run on the target hardware to implement the filter (1008). For example, the code generator may be an HDL coder that generates HDL or VHDL. The HDL or VHDL may be passed to an FPGA to configure the FPGA to implement the filter.

The filter of the exemplary embodiments may be implemented via a number of different devices as will explained below. In some exemplary embodiments, the filter is realized via processing logic that is part of a computing environment. As has been explained above, programming language instructions may be executed on the processing logic to realize the functionality of a filter. In other exemplary embodiments the filter is realized in processing logic in devices like receivers, transmitters, or filtering devices as will be explained below.

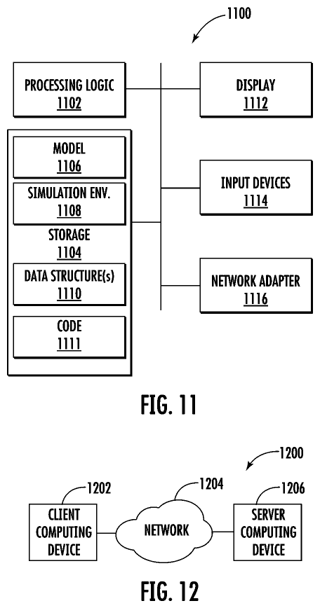

FIG. 11 depicts a block diagram of a computing environment 1100 suitable for practicing an exemplary embodiment. The computing environment 1100 may be a desktop computer, a laptop computer, a tablet computer, an embedded system, or other type of computing environment. The computing environment 1100 may include a processing logic 1102. The processing logic 1102 may be a central processing unit (CPU), a graphical processing unit (GPU), a field programmable gate array (FPGA), an application specific integrated circuit (ASIC), a controller, electronic circuitry or a combination thereof. The processing logic 1102 may execute instructions to realize the functionality of a filter of the exemplary embodiments described herein. The programming language instructions may be written by a developer or may be generated from a model as described above. Alternatively, the processing logic may be configurable by configuration settings to realize the functionality of the filter. The processing logic 1102 has access to a storage 1104. The storage 1104 may be a magnetic storage device, an optical storage device, or a combination thereof. The storage may include solid state storage, hard drives, removable storage elements such as magnetic disks, optical disks, thumb drives, or the like. The storage 1104 may include RAM, ROM, and other varieties of integrated circuit storage devices.

The storage 1104 may hold computer-executable instructions as well as data, documents, and the like. In FIG. 11 the storage 1104 is shown storing a simulatable or executable model 1106. The model 1106 may be a graphical model, a textual model, or a combination thereof. The storage 1104 may include a simulation environment 1108, such as has been described above. The simulation environment 1108 may simulate the model 1106, and the functionality described above for the exemplary embodiments may be realized as part of the simulation environment 1108 and model 1106. The storage 1104 may also store the data structure(s) 1110 described above. The storage 1104 may store code 1111 (e.g., programming language instructions) for performing operations such as the filtering described herein, or for other applications. The computing device 1100 may include a display device 1112 for displaying video output. Examples include LED displays, LCD displays, and retinal displays. The computing device 1100 may include input devices 1114 such as a keyboard, mouse, microphone, scanner, pointing device, or the like. The computing device 1100 may include a network adapter 1116 for interfacing the computing device with a network, such as a local area network or a network that provides access to a remote network like the Internet or another web-based network.

FIG. 12 depicts an illustrative distributed environment 1200 suitable for practicing exemplary embodiments. A client computing device 1202 is interfaced with a network 1204, such as a wide area network like the Internet, that is also interfaced with a server computing device 1206. The client computing device 1202 may include client code or a web browser for communicating with the server computing device 1206. For example, the simulation environment may run on the server computing device and a client on the client computing device 1202 may request that server computing device 1206 simulate the model and return the results. The model may include a filter that is capable of processing more than one input sample per cycle. The server computing device 1206 may have a form like that shown in FIG. 11. The client computing device 1202 may have components like that shown in FIG. 11.

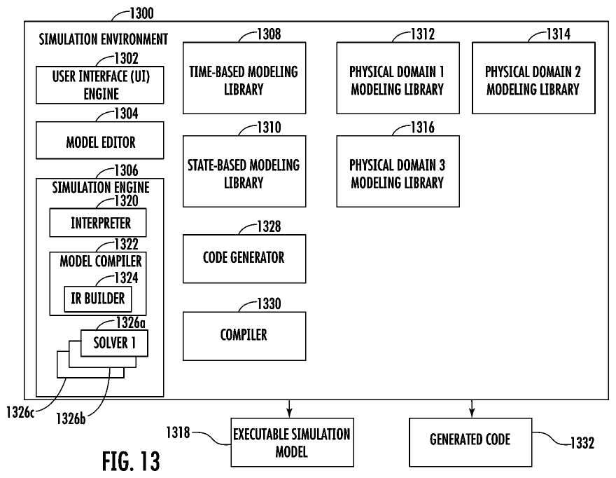

FIG. 13 is a partial functional diagram of an example simulation environment 1300 that may be used in some exemplary embodiments. The simulation environment 1300 may include a user interface (UI) engine 1302, a model editor 1304, a simulation engine 1306, and one or more data stores, such as libraries, that contain predefined model element types. For example, the simulation environment may include a time-based modeling library 1308, a state-based modeling library 1310, and one or more physical domain modeling libraries, such as physical domain modeling libraries 1312, 1314, and 1316, for modeling different physical systems. Exemplary physical domains include electrical, hydraulic, magnetic, mechanical rotation, mechanical translation, pneumatic, thermal, etc. Instances of the model element types provided by the libraries 1308, 1310, may be selected and included in an executable simulation model 1318, e.g., by the model editor 1304. The simulation engine 1306 may include an interpreter 1320, a model compiler 1322, which may include an Intermediate Representation (IR) builder 1324, and one or more solvers 1326a-c. Exemplary solvers include one or more fixed-step continuous solvers, which may utilize integration techniques based on Euler's Method or Huen's Method, and one or more variable-step solvers, which may be based on the Runge-Kutta and Dormand-Prince pair. A description of suitable solvers may be found in the Simulink User's Guide from The MathWorks, Inc. (September 2019 ed.), which is hereby incorporated by reference in its entirety.

In some embodiments, one or more block types may be selected from the libraries 1308 and/or 1310 and included in the executable simulation model 1318, such that the model 1318 may include an acausal portion and a causal portion. In exemplary embodiments the model 1318 may be a model of the filter and may include the filter as a modeled component in the model 1318.

The simulation environment 1300 may include or have access to other components, such as a code generator 1328 and a compiler 1330. The code generator 1328 may generate code, such as code 1332, based on the executable simulation model 1318. For example, the code 1332 may have the same or equivalent functionality and/or behavior as specified by the executable simulation model 1318. The generated code 1332, however, may be in form suitable for execution outside of the simulation environment 1300. Accordingly, the generated code 1332, which may be source code, may be referred to as standalone code. The compiler 1330 may compile the generated code 1332 to produce an executable, e.g., object code, that may be deployed on a target platform for execution, such as an embedded system.

Exemplary code generators include the Simulink HDL Coder, the Simulink Coder, the Embedded Coder, and the Simulink PLC Coder products from The MathWorks, Inc. of Natick, Mass., and the TargetLink product from dSpace GmbH of Paderborn Germany. Exemplary code 1336 that may be generated for the executable simulation model 1326 includes textual source code compatible with a programming language, such as the C, C++, C#, Ada, Structured Text, Fortran, and MATLAB languages, among others. Alternatively or additionally, the generated code 1336 may be (or may be compiled to be) in the form of object code or machine instructions, such as an executable, suitable for execution by a target device of an embedded system, such as a central processing unit (CPU), a microprocessor, a digital signal processor, etc. In some embodiments, the generated code 1332 may be in the form of a hardware description, for example, a Hardware Description Language (HDL), such as VHDL, Verilog, a netlist, or a Register Transfer Level (RTL) description. The hardware description may be utilized by one or more synthesis tools to configure a programmable hardware device, such as Programmable Logic Devices (PLDs), Field Programmable Gate Arrays (FPGAs), and Application Specific Integrated Circuits (ASICs), among others. The generated code 1332 may be stored in memory, such as a main memory or persistent memory or storage, of a data processing device.

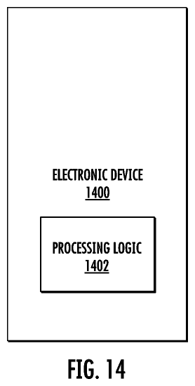

As mentioned above, the filter may be realized in a device other than a computer or other than in a computing environment. As shown in FIG. 14, the filter may be realized via processing logic 1402 in an electronic device 1400. The electronic device may be a digital filter device, a receiver, a transmitter or other type of electronic device where filtering is needed. The processing logic 1402 may be electronic circuitry, a CPU, a GPU, a FPGA, an ASIC, a controller or a combination thereof. The processing logic may, in some instances, execute programming language instructions or may be configurable via configuration settings to realize the functionality of the filter.

While the present invention has been described with reference to exemplary embodiments herein, it should be appreciated that various changes in form and detail may be made without departing from the intended scope of the present invention as defined in the appended claims.

1. A method, comprising:
receiving two or more input samples of data values; and
applying a filter operation on a first and a second input sample of data values in parallel to obtain filtered first and second input samples of data values, the filter operation comprises a recursive filter operation such that the filtering of the second input sample of data values that is subsequent in time relative to the first input sample of data values is dependent on the filtering of the first input sample of data values, the applying the filter operation comprises:
performing, with processing logic, polyphase decomposition of the recursive filter operation to generate a first filter operation for the first input sample of data values and a second filter operation for the second input sample of data values that filters the second input sample of data values independent of the first filter operation, and
performing the first and second filter operations on the first and second input samples of data values in parallel to produce the filtered first and second data input sample values.

2. The method of claim 1, where the applying a filter operation comprises applying one of a cascaded integrator comb (CIC) filter operation, a biquad filter operation, or an infinite impulse response (IIR) filter operation.

3. The method of claim 1, wherein the two or more input samples of data values are received in parallel as part of a frame and the filter operation is performed on the two or more input samples in the frame in parallel.

4. The method of claim 3, wherein there are more than two input samples of data values in the frame.

5. The method of claim 4, wherein there are N input samples in the frame, where N is a positive integer and wherein the performing, with processing logic, the polyphase decomposition of the recursive filter operation decomposes the recursive filter operation into N filter operations for filtering each of N input samples of data values.

6. The method of claim 5, wherein a magnitude of N is dictated by storage considerations and/or power considerations.

7. The method of claim 1, wherein the method is performed by executing a model on one or more processors, and wherein the model comprises a modeled filter that performs the applying a filter operation on a first and a second input sample of data values in parallel to obtain filtered first and second input samples of data values.

8. The method of claim 1, wherein the method is performed by a physical device.

9. The method of claim 7, further comprising generating programming language instructions from the model, wherein when executed, the programming language instructions perform the method.

10. The method of claim 9, wherein the programming language instructions are generated in one of the following programming languages: VHDL, Verilog language, C language C++ language, Python language, or Java language.

11. The method of claim 1, wherein the processing logic is one of a central processing unit (CPU), a graphics processing unit (GPU), a field programmable gate array (FPGA), an application specific integrated circuit (ASIC) or a digital signal processor (DSP).

12. A non-transitory computer-readable storage media storing instructions executable by processing logic to cause the processing logic to perform the following:
receive two or more input samples of data values; and
apply a filter operation on a first and a second input sample of data values in parallel to obtain filtered first and second input samples of data values, the filter operation comprises a recursive filter operation such that the filtering of the second input sample of data values that is subsequent in time relative to the first input sample of data values is dependent on the filtering of the first input sample of data values, the apply the filter operation comprising:
perform polyphase decomposition of the recursive filter operation to generate a first filter operation for the first input sample of data values and a second filter operation for the second input sample of data values that filters the second input sample of data values independent of the first filter operation, and
perform the first and second filter operations on the first and second input samples of data values in parallel to produce the filtered first and second data input sample values.

13. The non-transitory computer-readable storage media of claim 12, where the apply a filter operation comprises apply one of a cascaded integrator comb (CIC) filter operation, a biquad filter operation, or an infinite impulse response (IIR) filter operation.

14. The non-transitory computer-readable storage media of claim 12, wherein the two or more input samples of data values are received in parallel as part of a frame and the filter operation is performed on the two or more input samples in the frame in parallel

15. The non-transitory computer-readable storage media of claim 14, wherein there are more than two input samples of data values in the frame.

16. The non-transitory computer-readable storage media of claim 14, wherein there are N input samples in the frame, where N is a positive integer and wherein the performing, with processing logic, the polyphase decomposition of the recursive filter operation decomposes the recursive filter operation into N filter operations for filtering each of N input samples of data values.

17. The non-transitory computer-readable storage media of claim 16, wherein a magnitude of N is dictated by storage considerations and/or power considerations.

18. The non-transitory computer-readable storage media of claim 12, wherein a model is executed on one or more processors and wherein the model comprises a modeled filter that performs the applying a filter operation on a first and a second input sample of data values in parallel to obtain filtered first and second input samples of data values.

19. The non-transitory computer-readable storage media of claim 12, wherein the method is performed by a physical device.

20. The non-transitory computer-readable storage media of claim 18, further storing instructions for generating programming language instructions from the model, wherein when executed, the programming language instructions performs the receiving two or more input samples of data values and the applying a filter operation on a first and a second input sample of data values in parallel to obtain filtered first and second input samples of data values.

21. The non-transitory computer-readable storage media of claim 20, wherein the programming language instructions are generated in one of the following programming languages: VHDL, Verilog language, C language C++ language, Python language, or Java language.

22. The non-transitory computer-readable storage media of claim 12, wherein the processing logic is one of a central processing unit (CPU), a graphics processing unit (GPU), a field programmable gate array (FPGA), an application specific integrated circuit (ASIC), or a digital signal processor (DSP).

23. Processing logic configured to perform the following:
receive two or more input samples of data values; and
apply a filter operation on a first and a second input sample of data values in parallel to obtain filtered first and second input samples of data values, the filter operation comprises a recursive filter operation such that the filtering of the second input sample of data values that is subsequent in time relative to the first input sample of data values is dependent on the filtering of the first input sample of data values, the apply the filter operation comprises:
perform polyphase decomposition of the recursive filter operation to generate a first filter operation for the first input sample of data values and a second filter operation for the second input sample of data values that filters the second input sample of data values independent of the first filter operation, and
perform the first and second filter operations on the first and second input samples of data values in parallel to produce the filtered first and second data input sample values.

24. The processing logic of claim 23, wherein the processing logic is one of a central processing unit (CPU), a graphics processing unit (GPU), a field programmable gate array (FPGA), an application specific integrated circuit (ASIC), or a digital signal processor (DSP).

25. The processing logic of claim 23, wherein the processing logic includes multiple cores, processors and/or logic elements for performing the first filter operation and the second filter operation in parallel.

26. A method, comprising:
analyzing a model that comprises model portions representing functionalities of a recursive filter operation on two or more input samples of data values, wherein the filtering of the second input sample of data values that is subsequent in time relative to the first input sample of data values is dependent on the filtering of the first input sample of data values; and
generating program code for the model, wherein generating the program code comprises
generating first program code for a filter operation to apply on a first input sample of data values,
generating second program code for a filter operation to apply on a second input sample of data values, wherein
the first filter operation and the second filter operation are polyphase decomposed filter operations of the recursive filter operation, and
the first program code and second program code are executable in parallel to obtain filtered first and second input samples of data values.

27. The method of claim 26, wherein the generating code comprises analyzing the model.

28. The method of claim 27, wherein the analyzing comprises polyphase decomposition of a transfer function for the recursive filter operation.

29. The method of claim 26, wherein the generated program code comprises code generated in one of the following programming languages: VHDL, Verilog language, C language C++ language, Python language, or Java language.

30. A non-transitory computer-readable storage media storing instructions executable by processing logic to cause the processing logic to perform the following:
analyze a model that comprises model portions representing functionalities of a recursive filter operation on two or more input samples of data values, wherein the filtering of the second input sample of data values that is subsequent in time relative to the first input sample of data values is dependent on the filtering of the first input sample of data values; and
generate program code for the model, wherein generating the program code comprises generating first program code for a filter operation to apply on a first input sample of data values,
generate second program code for a filter operation to apply on a second input sample of data values, wherein
the first filter operation and the second filter operation are polyphase decomposed filter operations of the recursive filter operation, and
the first program code and second program code are executable in parallel to obtain filtered first and second input samples of data values.
